(19) United States
(12) Patent Application Publication
(10) Pub. No.: US 2021/0371442 A1
(43) Pub. Date: Dec. 2, 2021

(54) ORGANOMETALLIC COMPOUNDS

(71) Applicant: Umicore AG & Co. KG, Hanau-Wolfgang (DE)

(72) Inventors: Wolf SCHORN, Waldbronn (DE); Annika FREY, Hanau (DE); Eileen WÖRNER, Nidderau (DE); Angelino DOPPIU, Seligenstadt (DE); Ralf KARCH, Kleinostheim (DE)

(21) Appl. No.: 17/263,700

(22) PCT Filed: Jul. 26, 2019
(86) PCT No.: PCT/EP2019/070208

§ 371 Date: Jan. 27, 2021

(30) Foreign Application Priority Data
Jul. 27, 2018 (EP) 18186140.2
Nov. 7, 2018 (DE) 102018127836.5

(51) Int. Cl. C07F 15/06; C23C 16/18

(52) U.S. Cl. CPC C07F 15/06; C23C 16/18

(57) ABSTRACT

The present patent application relates to novel allyl cobalt complexes, to a process for their preparation and to their use for vapor deposition.

Allyl-cobalt complexes having the general formula [Co(η³-C₃H₄—R1)(CO)₃] or [Co(η³-allyl-R1)(CO)₃], in particular [Co(η³-C₃H₅)(CO)₃] and methods for their preparation have found increased interest in the recent past.

Chatani et al, Tetrahedron Letters 24, (1983), 5649-5652 shows a synthesis of (η³-allyl)Co(CO)₃ by reaction of cobalt octacarbonyl Co₂(CO)₈ with trimethylsilane and subsequent reaction with allyl acetate in benzene as a solvent. Chatani indicates the yields for the first stage as 85%, the allyl acetate-related yield of the second stage as 52%. In the optimization of this synthesis, it was found that the cobalt-related overall yield of this process over both stages was not more than 25%.

KR 101587509 describes a synthesis of (η³-allyl)Co(CO)₃ by reaction of cobalt octacarbonyl Co₂(CO)₈ in ethereal solution with aqueous sodium hydroxide in the presence of benzyltriethylammonium chloride as a phase transfer catalyst and subsequent addition of allyl bromide. The organic phase is then separated, dried and the reaction product is purified by distillation after removal of the solvent, wherein the reaction product was obtained in a cobalt-related overall yield of 38% over both stages.

It was the object of the invention to provide a process for the preparation of allyl-cobalt complexes having the general formula [Co(η³-C₃H₄—R1)(CO)₃] or [Co(η³-Allyl-R1)(CO)₃], in particular [Co(η³-C₃H₅)(CO)₃], which allows improved yields.

Surprisingly, it was found, that this task is solved by a process for the preparation of allyl-cobalt complexes having the general formula [Co(η³-C₃H₄—R1)(CO)₃] or [Co(η³-Allyl-R1)(CO)₃] comprising the steps of
a. reaction of cobalt octacarbonyl Co₂(CO)₈ with a trialkylhydrosilane of formula (R2)₃Si—H to a cobalt complex of general formula [(R2)₃Si—Co(CO)₄];
b. reaction of the resulting cobalt complex having the general formula [(R2)₃Si—Co(CO)₄] with an organic ester having the general formula R3-(CO₂-allyl-R1)ₓ where X=1, 2 or 3 to form the cobalt complex [Co(η³-C₃H₄—R1)(CO)₃].

In an optional step c, the reaction product, i.e. the allyl cobalt complex having general formula [Co(η³-C₃H₄—R1)(CO)₃] or [Co(η³-allyl-R1)(CO)₃], can be removed from the reaction mixture, in particular by distillation. In this case, it is advantageous that no fractional distillation is required and thus a very simple separation of the reaction product is possible.

R1 and R2 independently represent hydrogen or alkyl.

R1 may in particular denote hydrogen, C1 to C5 alkyl and C1 to C5 cycloalkyl and is in particular selected from the group consisting of H, methyl, ethyl, n-propyl, isopropyl, n-butyl, tert-butyl, cyclobutyl and combinations thereof.

R2 may in this case particularly denote hydrogen and C1 to C5 alkyl and is in particular selected from the group consisting of H, methyl, ethyl, n-propyl, isopropyl, n-butyl and combinations thereof.

R3 is alkyl, cycloalkyl or aryl and may in particular be a C3 to C10 alkyl, cycloalkyl or aryl, which may be substituted or condensed with a C1 to C8 alkyl or cycloalkyl. In particular, R3 may be selected from hexyl, heptyl, octyl, cyclohexyl, cyclooctyl, phenyl, 4-toluyl, 2-cyclohexylethyl or combinations thereof.

The organic ester having the general formula R3-(CO₂-allyl-R1)ₓ may be a compound in which x=1, 2 or 3. In particular, x may be 1 or 2. In particular when R3 is an aromatic or cycloalkyl, x may be 2 or 3, advantageously 2. When R3 is alkyl, then x is advantageously 1. In a specific embodiment, the organic ester having the general formula R3-(CO₂-allyl-R1)ₓ is a heptanoate of the C₆H₁₃CO₂-allyl-R1 type, wherein R1 is as defined above, in particular where R1=H, methyl, ethyl, isopropyl or tert-butyl.

In step a, it has proven successful when cobalt octacarbonyl Co₂(CO)₈ is added first and the trialkylhydrosilane having formula (R2)₃Si—H is gradually added, wherein good results may be achieved with triethylhydrosilane, i.e. a compound in which R2 is ethyl. Since this is an exothermic reaction, the reaction temperature can also, but not only, be controlled by the rate of addition of the trialkylhydrosilane.

The trialkylhydrosilane can be added first in equimolar ratio relative to the cobalt octacarbonyl Co₂(CO)₈. Good results were obtained with a slight excess of 1.01 to 1.3, in particular 1.02 to 1.2 or 1.04 to 1.1 equivalents of trialkylhydrosilane, in particular triethylhydrosilane. The yields at this stage are usually 95 to 98%.

Suitable solvents are generally branched or unbranched alkanes, ethers or aromatics, in particular those having 5 to 10 carbon atoms. This includes, for example, solvents such as pentane, hexane, heptane, octane, benzene, toluene, diethyl ether, diisopropyl ether, tetrahydrofuran, dioxane or combinations thereof. Good results can be achieved in particular with heptane.

The reaction temperature is generally at room temperature, that is to say about 15° C. to 55° C. or 20° C. to 40° C., in particular 20 to 25° C. The rate of addition and thus also the reaction time therefore depend on the desired reaction temperature. Times of from two to eight, in particular from 3 to 5 or from 2.5 to 4.5 hours, are generally suitable.

Subsequently, the reaction mixture may be maintained at a temperature of from about 15° C. to 30° C., more preferably from 20 to 25° C., which may be higher, lower, or equal to the reaction temperature. Stirring can be effected at this temperature for 6 to 24 hours, in particular 8 to 18 hours or 6 to 12 hours. The end of the reaction can easily be detected by the fact that gas evolution no longer occurs.

The solvent and optionally excess silane may thereafter be removed. This can be achieved, for example, by distillation, wherein, if appropriate, a suitable negative pressure can be applied in order to allow distillation at lower temperatures. Usually, a pressure of less than 100 mbar is sufficient in the distillation; pressures in the range from 15 to 70 mbar or 25 to 50 mbar have proven effective. In general, temperatures of 30° C. to 70° C., in particular 40° C. to 50° C. have proven effective.

The temperatures and pressures are evident to the person skilled in the art from the boiling point of the substances to be distilled off and the desired temperature in order to achieve a gentle separation of substances. The thus obtained cobalt complex having the general formula [(R2)₃Si—Co(CO)₄] can then be reacted further in the following process step.

The reaction of the resulting cobalt complex having the general formula [(R2)₃Si—Co(CO)₄] with an organic ester having general formula R3-(CO₂-allyl-R1)ₓ where x=1, 2 or 3 and wherein R1 and R3 are defined as described above, takes place in step b.

The organic ester having general formula R3-(CO₂-allyl-R1)ₓ is preferably used at least an equimolarly to the cobalt complex having general formula [(R2)₃Si—Co(CO)₄], but can also be used in excess, wherein a 1.1 to double molar excess is sufficient and a still greater excess is harmless.

In the reaction, a solvent having a boiling point of greater than about 200° C. at atmospheric pressure may be used. Good results can be achieved, for example, with long-chain aliphatic hydrocarbons, in particular with branched or unbranched alkanes having more than 14 carbon atoms, wherein mostly those having 19 or fewer carbon atoms have proven successful. Suitable solvents are, for example, tetradecane, pentadecane, hexadecane, heptadecane, octadecane, nonadecane, but alkanes having more than 19 carbon atoms, such as up to 34 carbon atoms, may also be used, particularly when these are liquid at room temperature or at least at the reaction temperature, such as botryococcane and 2,6,10,15,19,23-hexamethyltetracosane (squalane). Suitable solvents are therefore, for example, tetradecane, pentadecane, hexadecane, heptadecane, octadecane, nonadecane, botryococcane, 2,6,10,15,19,23-hexamethyltetracosane (squalane) and combinations thereof.

In a specific embodiment, the organic ester having the general formula R3-(CO₂-allyl-R1)ₓ may also be used as solvent, provided that it has a boiling point of more than approximately 200° C. In particular, the heptanoate of the C₆H₁₃CO₂-allyl-R1 type has proven successful, in particular R1 can denote C1 to C5-alkyl and C3 to C5-cycloalkyl, and is in particular selected from the group consisting of H, methyl, ethyl, n-propyl, isopropyl, n-butyl, tert-butyl, cyclobutyl and combinations thereof.

In principle, the sequence of addition of the reactants, of the cobalt complex having the general formula [(R2)₃Si—Co(CO)₄] and the organic ester of general formula R3-(CO₂-allyl-R1)ₓ, is not critical. It has proven successful to add the cobalt complex first, optionally adding the solvent and, after a possible stirring time, to gradually add the organic ester once the cobalt complex has dissolved or a homogeneous suspension has formed. The reaction temperature is about 20° C. to 90° C., in particular 40° C. to 80° C. or 60° C. to 80° C. Good results can be obtained at 65° C. to 75° C. Since the reaction is exothermic, the heating can be effected by adding the ester having the general formula R3-(CO₂-allyl-R1)ₓ, although the carrying out of the process can be accelerated by preheating to the reaction temperature. The rate of addition may then be selected such that the reaction temperature does not vary excessively, for example by no more than ±5° C., or the temperature is maintained substantially constant by heating. If the addition is concluded, the reaction temperature can be maintained with stirring to complete the reaction, wherein generally not more than 1 to 8 hours, in particular 1.5 to 5 or 2 to 4 hours, suffice. The end of the reaction can easily be detected by the fact that gas evolution no longer occurs. In this step, since the desired reaction product is the lightest volatile compound, it is simply distilled off. In general, distillation temperatures of 60° C. to 100° C. at a pressure of less than 25 mbar have proven successful. Good results can be achieved at temperatures of from 60° C. to 80° C. and a pressure of less than 10 bar, wherein, if appropriate, the pressure can be lowered successively at a constant temperature. The condenser may be cooled to temperatures of less than 60° C., such as from 15° C. to 50° C., or from 20° C. to 45° C.

The process for the preparation of allyl-cobalt complexes having the general formula [Co(η³-C₃H₄—R1)(CO)₃] or [Co(η³-allyl-R1)(CO)₃] can also be carried out as a single pot reaction. To this end, after completion of step a, the solvent and excess trialkylhydrosilane may be distilled off, and thereafter the solvent of step b and the organic ester having the general formula R3-(CO₂-allyl-R1)ₓ may be added.

In a simplified configuration of this embodiment, the distillation of the solvent and excess trialkylhydrosilane is dispensed with and the organic ester having the general formula R3-(CO₂-allyl-R1)ₓ and optionally the solvent are added instead. It is advantageous in general, but particularly in this process, if the organic ester having the general formula R3-(CO₂-allyl-R1)ₓ is used as solvent. Since after step b has been carried out excess trialkylhydrosilane and the solvent from step 1 are still present in the reaction mixture in this process variant, fractional distillation is necessary depending on the boiling point of the end product. On the other hand, upon isolation of the product from step a, or at least after removal of solvent and trialkylhydrosilane following completion of step a, fractional distillation following completion of step a can often be dispensed with and the end product recovered by simple distillation.

### EXAMPLES

### Example 1

### Step a.: Reaction of Dicobalt Octacarbonyl with Triethylsilane to Triethylsilyl Cobalt Tetracarbonyl

In a 4 liter 4 neck glass flask equipped with a KPG stirrer, a temperature sensor for controlling the internal temperature, a dropping funnel without gas compensation and an intensive cooler with a pressure relief valve, 638 g of dicobalt octacarbonyl (1.86 mol, 1.00 eq.) are introduced and slurried with 1.00 liter of heptane. The reaction flask is maintained at 20±4° C. by means of a water bath. The reaction mixture is stirred at 300 rpm. This is followed by dropwise addition of 467 g of triethylsilane (4.02 mol, 2.15 eq.) over the course of four hours, in which case it is ensured that the internal temperature is in the range of 20±4° C. After the end of the addition, the triethylsilane container is rinsed with 100 mL of heptane and the heptane/triethylsilane mixture is added to the reaction mixture. The reaction mixture is stirred at room temperature overnight. The next day, the heptane solvent and excess triethylsilane are distilled off from the reaction mixture at 50° C. internal temperature and a pressure of 30 mbar. When the distillate stream begins to run dry, the pressure is successively reduced to a final pressure of 18 mbar. The product remains in the reaction flask. Isolated: 1095 g.

The product can be subjected to a purification step:

For this purpose, the product is condensed in dynamic vacuum. The internal temperature is 50° C., the condenser is cooled with 0° C., and the vacuum is <1*10⁻³ mbar. 573 g of crude product thus yield 534 g of purified material.

### Example 2

### Step b.: Reaction of Triethylsilyl Cobalt Tetracarbonyl with Allyl Heptanoate to [Co(η³-C₃H₅)(CO)₃]

400 g of purified triethylsilyl cobalt tetracarbonyl (1.40 mol, 1.00 eq.) is introduced into a 4 liter 4-neck glass flask equipped with magnetic stirring core, an intensive cooler with a pressure relief valve, a dropping funnel without gas compensation, a temperature sensor for controlling the internal temperature and a distillation column in combination with a distillation bridge and a condenser. The system can be rendered inert and also evacuated via the condenser. The intensive cooler and the distillation bridge are cooled to −10° C. For the first part of the reaction, the released gas is discharged via the intensive cooler with pressure relief valve. The reaction mixture is stirred at 300 rpm, heated to 70° C. internal temperature, and at this temperature 263 g of allyl heptanoate (1.54 mol, 1.10 eq.) are added dropwise. This takes place within 70 minutes, in which case the dropping rate is adjusted in such a way that the internal temperature remains at 70±5° C. After the end of the addition, the reaction mixture is stirred for a further three hours at 70° C. until no further evolution of gas is observed. The second part of the reaction consists of distillation of the crude product. The condenser is cooled to about −40° C. and, with stirring at 300 rpm, vacuum is slowly applied to the apparatus via the condenser at a sump temperature of 70° C. At a pressure of 29 mbar, the product begins to distill. When the distillate stream tends to sediment, the pressure is successively reduced to 7 mbar. This yields 236 g of the crude product (1.29 mol, 92%) with a purity of 99 m %.

The crude product can be purified by fine distillation:

Distillation at an internal temperature of 40° C. and a pressure of 10 mbar via a Vigreux column yields 92% of a product which has a purity of >99 m % of [Co(η³-C₃H₅)(CO)₃].

### Example 3

### Step b.: Reaction of Triethylsilyl Cobalt Tetracarbonyl with Diallyl Phthalate to [Co(η³-C₃H₅)(CO)₃]

100 g of purified triethylsilyl cobalt tetracarbonyl (0.35 mol, 1.00 eq.) were introduced into a 500 ml 4-neck glass flask equipped with magnetic stirring core, an intensive cooler with a pressure relief valve, a dropping funnel with gas compensation, a temperature sensor for controlling the internal temperature and a distillation bridge with a receiver. The system may be evacuated and inertized. The distillation bridge was cooled to −25° C. The triethylsilyl cobalt tetracarbonyl was stirred at 300 rpm, heated to 70° C. internal temperature and at this temperature 47.8 g of diallyl phthalate (0.19 mol, 0.55 eq.) were added dropwise. This addition was taking place within 70 minutes and the dropping rate was adapted in such a way that the internal temperature was at 70±5° C. After the addition, the reaction mixture was further stirred at 70° C. internal temperature for three more hours until no more gas evolution could be observed.

The second part of the reaction was consisting of the distillation of the raw product. The receiver was cooled to about −40° C. and while stirring the reaction mixture at 300 rpm at a temperature of 70° C., the apparatus was slowly evacuated via the receiver. At a pressure of 30 millibar the product started to distill. When the flow of distillate was about to run dry, the pressure was further reduced successively to a final pressure of 10 millibar. 60.3 g of raw product (0.33 mol, 94%) with a purity of >99% were obtained.

1.-18. (canceled)

19. A method for the preparation of allyl-cobalt complexes having the general formula [Co(η³-C₃H₄—R1)(CO)₃] or [Co(η³-allyl-R1)(CO)₃] comprising the steps of
a) reacting cobalt octacarbonyl Co₂(CO)₈ with a trialkylhydrosilane of the form (R2)₃Si—H to a cobalt complex having the general formula [(R2)₃Si—Co(CO)₄];
b) reacting the resulting cobalt complex having the general formula [(R2)₃Si—Co(CO)₄] with an organic ester having the general formula R3-(CO₂-Allyl-R1) where X=1, 2 or 3, to cobalt complex [Co(η³-C₃H₄—R1)(CO)₃], wherein R1 and R2 are independently hydrogen or alkyl and R3 is alkyl, cycloalkyl or aryl.

20. The method according to claim 19, wherein R1 is selected from the group consisting of H, methyl, ethyl, n-propyl, isopropyl, n-butyl, tert-butyl, cyclobutyl and combinations thereof.

21. The method according to claim 19, wherein R2 is selected from the group consisting of H, methyl, ethyl, n-propyl, isopropyl, n-butyl, and combinations thereof.

22. The method according to claim 19, wherein R3 is a C3 to C10 alkyl, cycloalkyl or aryl, which may be substituted or condensed with a C1 to C8 alkyl or cycloalkyl.

23. The method according to claim 19, wherein R3 is selected from hexyl, heptyl, octyl, cyclohexyl, cyclooctyl, phenyl, 2-cyclohexylethyl or combinations thereof.

24. The method according to claim 19, wherein the organic ester having the general formula R3-(CO₂-allyl-R1)ₓ is a heptanoate of the C₆H₁₃CO₂-allyl-R1 type.

25. The method according to claim 19, wherein in step b) a solvent is used which has a boiling point of more than 200° C. at atmospheric pressure.

26. The method according to claim 19, wherein the organic ester having the general formula R3-(CO₂-allyl-R1)ₓ or squalane is used as the solvent having a boiling point of more than 200° C. at atmospheric pressure.

27. The method according to claim 19, wherein the reaction temperature in step a) is between 20° C. and 55° C., or between 25° C. and 30° C.

28. The method according to claim 19, wherein in step a) branched or unbranched alkanes, ethers or aromatics having 5 to 10 carbon atoms are used as the solvent.

29. The method according to claim 19, wherein the solvent used in step a) is pentane, hexane, heptane, octane, benzene, toluene, diethyl ether, diisopropyl ether, tetrahydrofuran, dioxane or combinations thereof.

30. The method according to claim 19, wherein the cobalt complex [Co(η³-C₃H₄—R1)(CO)₃] is produced in a single pot method.

31. The method according to claim 19, wherein the cobalt complex [Co(η³-C₃H₄—R1)(CO)₃] is produced in a single pot method, a solvent is used in step a) and this is removed before carrying out step b).

32. The method according to claim 19, further comprising a step c), wherein in step c) the cobalt complex [Co(η³-C₃H₄—R1)(CO)₃] is removed from the reaction mixture.

33. The method according to claim 19, further comprising a step c), wherein in step c) the cobalt complex [Co(η³-C₃H₄—R1)(CO)₃] is removed from the reaction mixture by distillation.

34. A method for the vapor deposition of cobalt-containing layers comprising the steps of
providing allyl-cobalt complexes having the general formula [Co(η³-C₃H₄—R1)(CO)₃] or [Co(η³-allyl-R1)(CO)₃] according to claim 19;
employing the allyl-cobalt complexes having the general formula [Co(η³-C₃H₄—R1)(CO)₃] or [Co(η³-allyl-R1)(CO)₃] in a method for vapor deposition of cobalt-containing layers.

35. The method according to claim 34, wherein the deposition is by thermal decomposition.

36. The method according to claim 34, wherein said method is an ALD (Atomic Layer Deposition) or CVD (Chemical Vapor Deposition) method.
